(19) United States
(12) Patent Application Publication
(10) Pub. No.: US 2022/0102938 A1
(43) Pub. Date: Mar. 31, 2022

(54) SUBSTRATE-TRANSFER VERTICAL CAVITY SURFACE EMITTING LASER AND METHOD FOR MANUFACTURE THEREOF

(71) Applicant: ZHEJIANG BERXEL PHOTONICS CO., LTD., Jiaxing City (CN)

(72) Inventor: Chihchiang SHEN, Jiaxing City (CN)

(21) Appl. No.: 17/425,065

(22) PCT Filed: Apr. 16, 2020
(86) PCT No.: PCT/CN2020/085162

§ 371 Date: Jul. 22, 2021

(30) Foreign Application Priority Data
Nov. 19, 2019 (CN) 201911137415.2
Jan. 19, 2020 (CN) 202010059560.X

(51) Int. Cl. H01S 5/024; H01S 5/183

(52) U.S. Cl. CPC H01S 5/02461; H01S 5/18311; H01S 5/02476; H01S 5/18377

(57) ABSTRACT

A substrate transfer vertical cavity surface emitting laser and method manufacturing thereof are disclosed. The structure of the substrate-transferred vertical-cavity surface-emitting laser comprises: a conductive heat dissipation substrate, a metal adhesion layer and a vertical-cavity surface-emitting laser. A first surface of the conductive heat dissipation substrate is adhered to the vertical-cavity surface-emitting laser chip via the metal adhesion layer. A second surface of the conductive heat dissipation substrate and the side of the vertical-cavity surface-emitting laser film chip that is away from the conductive heat dissipation substrate contains contact electrodes. The first surface and the second surface are two opposite sides of the conductive heat dissipation substrate. The conductive heat dissipation substrate is made of a material with excellent thermal conductivity, which facilitates heat dissipation of the vertical-cavity surface-emitting laser chip. Therefore, the present application significantly improves the power conversion efficiency of the vertical-cavity surface-emitting laser chip.

### TECHNICAL FIELD

The present invention generally relates to the technical field of lasers, in particular to a substrate-transfer vertical cavity surface emitting laser and method manufacturing thereof.

### BACKGROUND

When the vertical-cavity surface-emitting laser (VCSEL) chip is in use, a lot of heat is generated in the light-emitting layer. There is a gallium arsenide (GaAs) substrate with a thickness of about 100 μm below the conventional vertical-cavity surface-emitting laser chip, and the heat must be transferred to the backside metal via the GaAs substrate for heat dissipation. The conventional vertical-cavity surface-emitting laser chip is poor in heat dissipation due to the low thermal conductivity of GaAs and the long heat transfer distance.

### SUMMARY

The present application aims to provide a substrate-transferred vertical-cavity surface-emitting laser and a manufacturing method thereof to solve the problem of poor heat dissipation of the vertical-cavity surface-emitting laser in the prior art.

In the first aspect, the present application provides a substrate-transferred vertical-cavity surface-emitting laser, comprising:

a conductive heat dissipation substrate;

a metal adhesion layer; and

a vertical-cavity surface-emitting laser chip;

wherein a first surface of the conductive heat dissipation substrate is adhered to the vertical-cavity surface-emitting laser chip via the metal adhesion layer;

a second surface of the conductive heat dissipation substrate and the side of the vertical-cavity surface-emitting laser chip that is away from the conductive heat dissipation substrate contain contact electrodes, and

the first surface and the second surface are two opposite sides of the conductive heat dissipation substrate.

Further, the conductive heat dissipation substrate is a metal substrate made of a material including at least one of molybdenum, molybdenum copper alloy, tungsten, tungsten copper alloy, and chromium copper alloy; or

the conductive heat dissipation substrate is a silicon substrate.

Further, the vertical-cavity surface-emitting laser chip comprises a first reflector layer, a light-emitting layer and a second reflector layer;

one of the first reflector layer and the second reflector layer is a n-type reflector layer, and the other is a p-type reflector layer.

Further, the first reflector layer and the second reflector layer are at least one of a Bragg reflector layer and a high-contrast grating layer.

Further, the light-emitting layer comprises an active layer and an oxide layer, and one of the active layer and the oxide layer is connected to the n-type reflector layer, and the other is connected to the p-type reflector layer;

the oxide layer includes an unoxidized region and an oxidized region arranged around the unoxidized region, and the unoxidized region is used to define a light-emitting window.

Further, the light-emitting layer comprises an active layer and two oxide layers, the active layer is located between the two oxide layers, one of the oxide layers is connected to the n-type reflector layer, and the other oxide layer is connected to the p-type reflector layer;

each of the oxide layers includes an unoxidized region and an oxidized region arranged around the unoxidized region, and the unoxidized region is used to define a light-emitting window.

Further, the metal adhesion layer is made of a material including at least one of the following metals: Ti, Sn, Ge, Ni, In, Zn, Pt, Cr, Pd and Au.

Further, an electrical isolation region is formed by proton or ion implantation at least outside the light-emitting window, and the electrical isolation region covers at least a region of the oxide layer that is unoxidized.

Further, the electrical isolation region also covers at least a part of any one of the first reflector layer, the light-emitting layer, and the second reflector layer.

Further, the vertical-cavity surface-emitting laser chip has a plurality of light-emitting regions arranged in a matrix or arranged randomly.

In the second aspect, the present application provides a manufacturing method of a substrate-transferred vertical-cavity surface-emitting laser, comprising the steps of:

providing a conductive heat dissipation substrate;

adhering a vertical-cavity surface-emitting laser chip on the first surface of the conductive heat dissipation substrate via a metal adhesion layer using a metal bonding process;

forming contact electrodes respectively on the second surface of the conductive heat dissipation substrate and the side of the vertical-cavity surface-emitting laser chip that is away from the conductive heat dissipation substrate, wherein the first surface and the second surface are two opposite sides of the conductive heat dissipation substrate.

Further, the vertical-cavity surface-emitting laser chip is formed by the following process:

providing a substrate;

forming a first reflector layer on the substrate;

forming a light-emitting layer on the first reflector layer; and

forming a second reflector layer on the light-emitting layer, wherein one of the first reflector layer and the second reflector layer is a n-type reflector layer, and the other is a p-type reflector layer.

Further, a buffer layer is formed on the second reflector layer;

a first bonding metal film is formed on the buffer layer;

a second bonding metal film is formed on the first surface;

a metal bonding process is performed on the conductive heat dissipation substrate and the vertical-cavity surface-emitting laser chip, so that the first bonding metal film and the second bonding metal film form the metal adhesion layer; and

the substrate is thinned to 0-200 μm.

Further, the light-emitting layer comprises an active layer and an oxide layer, and one of the active layer and the oxide layer is connected to the n-type reflector layer, and the other is connected to the p-type reflector layer;

an oxidation trench is formed, which extends at least from the first reflector layer to the second reflector layer; and

a wet oxidation process is performed in the oxidation trench to form inwardly an oxidized region from the oxidation trench, the oxidized region surrounds an unoxidized region that is used to define a light-emitting window.

Further, the metal adhesion layer is made of a material including at least one of the following metals: Ti, Sn, Ge, Ni, In, Zn, Pt, Cr, Pd and Au; ,

the metal bonding process is performed at a temperature of 200° C.-900° C. and a pressure of 0.1 MPa-5 MPa.

In the above solution, the first surface of the conductive heat dissipation substrate is adhered to the vertical-cavity surface-emitting laser chip via the metal adhesion layer, and the heat generated when the vertical-cavity surface-emitting laser chip emits light is transferred to the conductive heat dissipation substrate via the metal adhesion layer. The conductive heat dissipation substrate is made of a material with excellent thermal conductivity, which facilitates heat dissipation of the vertical-cavity surface-emitting laser chip. Therefore, the present application significantly improves the power conversion efficiency of the vertical-cavity surface-emitting laser chip.

### BRIEF DESCRIPTION OF DRAWINGS

Other features, objectives and advantages of the present application will become more apparent by the following detailed description of the non-limiting embodiments with reference to the following drawings:

FIG. 1 is a schematic diagram of a substrate-transferred vertical-cavity surface-emitting laser according to an embodiment of the present application;

FIGS. 2-8 are schematic diagrams of a manufacturing process of a substrate-transferred vertical-cavity surface-emitting laser according to the present application;

FIG. 9 is a structure schematic diagram of the light-emitting layer in which two oxidation layers are provided according to an embodiment of the present application; and

FIG. 10 is a flow chart of a manufacturing method of a substrate-transferred vertical-cavity surface-emitting laser provided by an embodiment of the present application.

### DETAILED DESCRIPTION

The present application will be further described in detail with reference to the drawings and embodiments. It is appreciable that the specific embodiments described herein are only for explaining rather than limiting the related invention. In addition, it should be noted that for the convenience of description, only parts related to the related invention are shown in the drawings.

It should be noted that the embodiments and features in the embodiments in the present application can combine with each other if there is no conflict. The present application will be described below in detail with reference to the drawings and in conjunction with the embodiments.

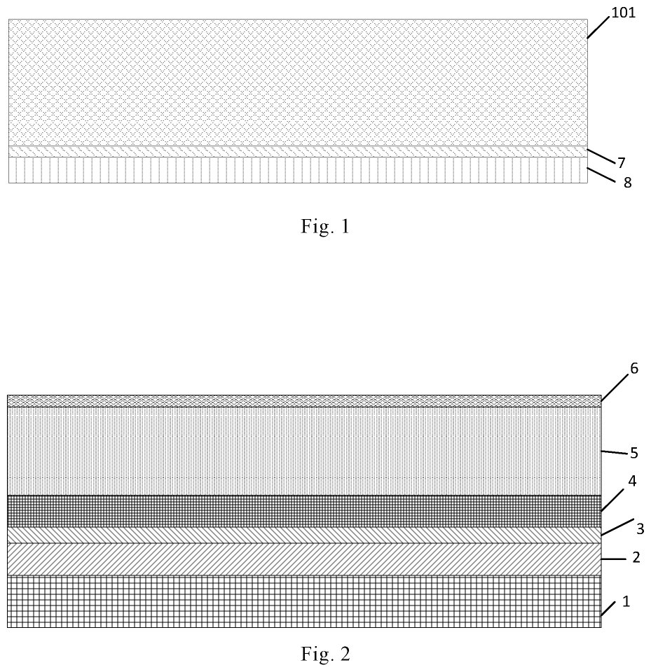

FIG. 1 is a substrate-transferred vertical-cavity surface-emitting laser according to an embodiment of the present application, comprising: a conductive heat dissipation substrate 8, a metal adhesion layer 7 and a vertical cavity surface generation laser chip 101. The conductive heat dissipation substrate 8 may be made of a material with high thermal conductivity, which may be metal, alloy or non-metal, etc. The examples of the material will be given below. A first surface of the conductive heat dissipation substrate 8 is adhered to the vertical-cavity surface-emitting laser chip 101 via the metal adhesion layer 7, and the conductive heat dissipation substrate 8 and the vertical cavity surface generation laser chip 101 are electrically connected to each other via the metal adhesion layer 7. The first surface of the conductive heat dissipation substrate 8 is connected to the vertical cavity surface generation laser chip 101 via the metal adhesion layer 7 by, for example, but not limited to, forming ohmic contact between the vertical cavity surface generation laser thin film chip 101 and the metal adhesion layer 7. The ohmic contact can be made by, for example, but not limited to, a metal bonding process, to achieve the purpose of improving heat dissipation. A second surface of the conductive heat dissipation substrate 8 and the side of the vertical-cavity surface-emitting laser film chip 101 that is away from the conductive heat dissipation substrate 8 contain contact electrodes (not shown in the figure). For example, a p-type electrode is electrically connected to the conductive heat dissipation substrate 8, and a n-type electrode is electrically connected to the side of the vertical-cavity surface-emitting laser chip 101 that is away from the conductive heat dissipation substrate 8; however, it is not limited to such configuration. The first surface and the second surface are two opposite sides of the conductive heat dissipation substrate 8.

It should be noted that the vertical-cavity surface-emitting laser chip 101 may include a plurality of light-emitting regions which may be arranged in matrix or arranged randomly.

In the above solution, the first surface of the conductive heat dissipation substrate 8 is adhered to the vertical-cavity surface-emitting laser chip via the metal adhesion layer 7, and the heat generated when the vertical-cavity surface-emitting laser chip emits light is transferred to the conductive heat dissipation substrate 8 via the metal adhesion layer 7. The conductive heat dissipation substrate 8 is made of a material with excellent thermal conductivity, which facilitates heat dissipation of the vertical-cavity surface-emitting laser chip. Thus, the present application significantly improves the power conversion efficiency of the vertical-cavity surface-emitting laser chip.

Further, the conductive heat dissipation substrate 8 is a metal substrate made of at least one of molybdenum, molybdenum copper alloy, tungsten, tungsten copper alloy and chromium copper alloy. When the conductive heat dissipation substrate 8 is a metal substrate, it is not easy to break after bonding, and the product yield of the substrate-transferred vertical-cavity surface-emitting laser can be improved.

Alternatively, the conductive heat dissipation substrate 8 is a silicon substrate.

Further, as shown in FIG. 8 below, the vertical-cavity surface-emitting laser chip comprises a first reflector layer, a light-emitting layer and a second reflector layer; one of the first reflector layer and the second reflector layer is a n-type reflector layer 2, and the other is a p-type reflector layer 5.

The first and the second reflector layer may be at least one of a distributed Bragg reflector (DBR) layer and a high contrast grating (HCG) layer. In other words, the first and the second reflector layer may be both DBR, the first and the second reflector layers may be both HCG, or one of the first and the second reflector layers is HCG and the other is DBR.

As one of the implementation modes, a p-type reflector layer 5 is provided on the metal adhesion layer 7, a light-emitting layer is provided on the p-type reflector layer 5, and an n-type reflector layer 2 is provided on the light-emitting layer.

Of course, a buffer layer can also be provided between the metal adhesion layer 7 and the p-type reflector layer 5, and the buffer layer may be one of GaAs, AlGaAs, InGaAs and AlInGaAs or laminated layers thereof. As one of the implementation modes, the buffer layer may be a p-type buffer layer 6 which uses p-type doped GaAs material.

In this example, the n-type reflector layer 2 is deposed above the light-emitting layer, that is, at the light-emitting side of the laser. Due to the low resistance of the n-type reflector layer 2, good laser beam quality can be obtained.

In another implementation mode, an n-type reflector layer 2 is provided on the metal adhesion layer 7. A light emitting layer is provided on the n-type reflector layer 2, and a p-type reflector layer 5 is provided on the light emitting layer.

Further, the light emitting layer comprises an active layer 4 and an oxide layer 3. One of the active layer 4 and the oxide layer 3 is connected to the n-type reflector layer 2 and the other is connected to the p-type reflector layer 5. The oxide layer 3 includes an unoxidized region 12 and an oxidized region 11 arranged around the unoxidized region 12, and the unoxidized region 12 is used to define the light-emitting window. The oxidized region 11 is an insulation area for isolating the current. The unoxidized region 12 is a conductive area where the current is conducted after a voltage is applied to the electrodes at both ends of the vertical-cavity surface-emitting laser chip. The active layer 4 is a multiple quantum well (MQW) layer, which emits light when it is electrified. Of course, in some examples, the active layer 4 may also be a single quantum well layer.

As one of the implementation modes, the p-type reflector layer 5 is provided on the metal adhesion layer 7; the active layer 4 is provided on the p-type reflector layer 5; the oxide layer 3 is provided on the active layer 4; and the n-type reflector layer 2 is provided on the oxide layer 3.

As one of the implementation modes, the p-type reflector layer 5 is provided on the metal adhesion layer 7; the oxide layer 3 is provided on the p-type reflector layer 5; the active layer 4 is provided on the oxide layer 3, and the n-type reflector layer 2 is provided on the active layer 4.

In another implementation mode, the n-type reflector layer 2 is provided on the metal adhesion layer 7; the active layer 4 is provided on the n-type reflector layer 2; the oxide layer 3 is provided on the active layer 4, and the p-type reflector layer 5 is provided on the oxide layer 3.

In yet another implementation mode, the n-type reflector layer 2 is provided on the metal adhesion layer 7; the oxide layer 3 is provided on the n-type reflector layer 2; the active layer 4 is provided on the oxide layer 3, and the p-type reflector layer 5 is provided on the active layer 4.

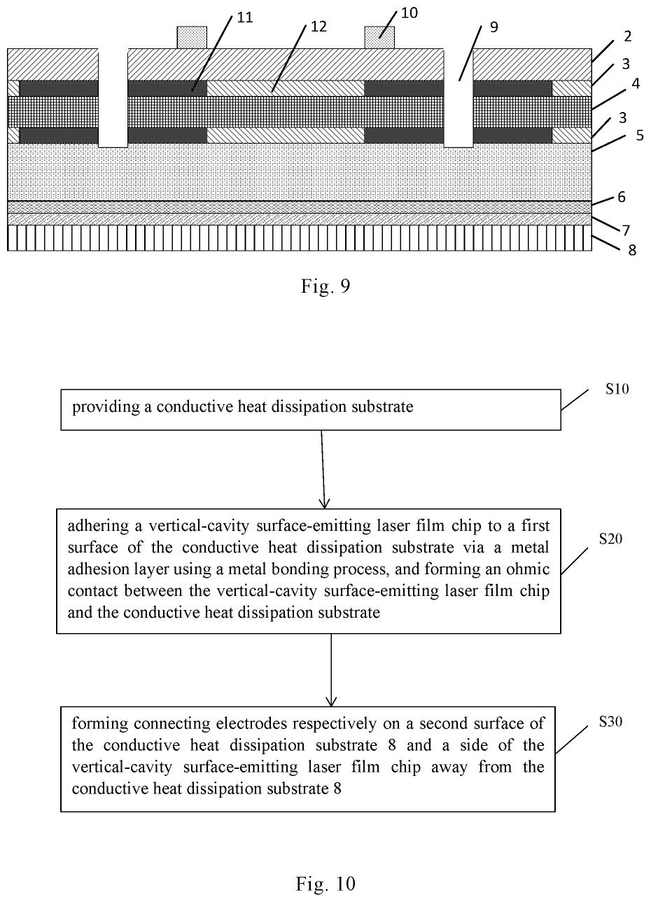

As shown in FIG. 9, as another implementation mode, the light-emitting layer comprises an active layer 4 and two oxide layers 3. The active layer 4 is deposed between the two oxide layers 3. One of the oxide layers 3 is connected to the n-type reflector layer 2, and the other oxide layer 3 is connected to the p-type reflector layer 5. Each of the oxide layers 3 includes an unoxidized region 12 and an oxidized region 11 arranged around the unoxidized region, and the unoxidized region 12 is used to define a light-emitting window, i.e., a light-emitting region.

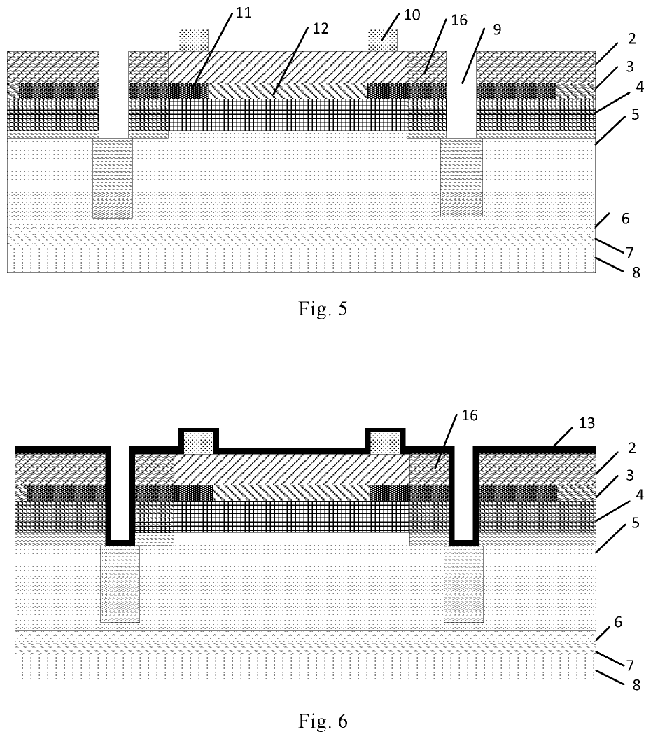

In addition, referring to at least FIG. 5, in order to better limit the flow path of the current, an electrical isolation region 16 is formed by proton or ion implantation at least outside the light-emitting window, and the electrical isolation region 16 covers at least a region of the oxide layer that is unoxidized. The term “cover” here does not mean that the electrical isolation region 16 is located above the oxide layer, but means that the electrical isolation region 16 is integrated with the oxide layer, and the integration depth may be set according to actual needs, that is, the electrical isolation region may completely pass through the oxide layer, or only extend into a part of the depth of the oxide layer.

Further, the electrical isolation region also covers at least a part of any one of the first reflector layer, the light emitting layer and the second reflector layer. For example, the electrical isolation region is formed in the light-emitting layer, the oxide layer and the first reflector layer, but not in the second reflector layer. In other words, the electric isolation region has a certain thickness, and its thickness does not start from the top surface of the second reflector layer. This structure is formed by performing proton or ion implantation according to the predetermined energy and concentration, and then performing annealing treatment according to the predetermined temperature and duration, so that the conductivity of the layers above the desired electrical isolation region, in the proton or ion implantation path, can be recovered. In this structure, the current is conducted via the uninsulated region and the unoxidized region 12 after a voltage is applied to the electrodes at both ends of the vertical-cavity surface-emitting laser chip.

Further, the metal adhesion layer 7 is made of a material including at least one of the following metals: Ti, Sn, Ge, Ni, in, Zn, Pt, Cr, PD and Au. The metal adhesion layer 7 is made of the above metal or alloy so that the metal bonding temperature can be lowered. For example, the bonding temperature may be between 200° C. and 900° C., which lowers the bonding process temperature, and thus effectively reduces the production cost and improves the product yield.

In the second aspect, as shown in FIG. 10, the present application provides a manufacturing method of a substrate-transferred vertical-cavity surface-emitting laser, which comprises the following steps:

S10: providing a conductive heat dissipation substrate 8; the conductive heat dissipation substrate 8 is a metal substrate made of a material including at least one of molybdenum, molybdenum copper alloy, tungsten, tungsten copper alloy and chromium copper alloy. The conductive heat dissipation substrate 8 is a metal substrate, and therefore it is not easy to break after bonding, and the product yield of the substrate-transferred vertical-cavity surface-emitting laser can be improved. Alternatively, the conductive heat dissipation substrate 8 is a silicon substrate.

S20: adhering a vertical-cavity surface-emitting laser chip to a first surface of the conductive heat dissipation substrate 8 via a metal adhesion layer 7 using a metal bonding process. After bonding, the first surface of the conductive heat dissipation substrate 8 is electrically connected to the vertical-cavity surface-emitting laser chip via the metal adhesion layer 7 by, for example, but not limited to, forming an ohmic contact between the vertical-cavity surface-emitting laser chip and the metal adhesion layer 7.

S30: forming contact electrodes respectively on a second surface of the conductive heat dissipation substrate 8 and a side of the vertical-cavity surface-emitting laser film chip that is away from the conductive heat dissipation substrate 8, wherein the first surface and the second surface are two opposite sides of the conductive heat dissipation substrate 8.

In the above solution, the first surface of the conductive heat dissipation substrate 8 is adhered to the vertical-cavity surface-emitting laser chip via the metal adhesion layer 7, and the heat generated when the vertical-cavity surface-emitting laser chip emits light is transferred to the conductive heat dissipation substrate 8 via the metal adhesion layer 7. The conductive heat dissipation substrate 8 is made of a material with excellent thermal conductivity, which facilitates heat dissipation of the vertical-cavity surface-emitting laser chip. Thus, the present application significantly improves the power conversion efficiency of the vertical-cavity surface-emitting laser film chip.

Further, the vertical-cavity surface-emitting laser chip is formed by the following process:

providing a substrate 1; the substrate 1 may be made of GaAs.

forming a first reflector layer on the substrate; the first reflector layer may comprise AlGaAs and/or GaAs which are two materials with different refractivity; the substrate and the first reflector layer may be both n-type or both p-type.

forming a light-emitting layer on the first reflector layer; the light-emitting layer at least comprises multi-quantum well layers which are laminated layers of GaAs, AlGaAs, GaAsP and InGaAs. The light-emitting layer is used to convert electric energy into light energy. Of course, in some examples, a single quantum well layer may replace a multiple quantum well layer.

forming a second reflector layer on the light emitting layer; the second reflector layer may comprise laminated layers of AlGaAs and GaAs which are two materials with different refractivity; the second reflector layer may be of p-type or n-type. When the first reflector layer is of n-type, the second reflector layer is of p-type, and vice versa.

Further, a buffer layer is formed on the second reflector layer; the buffer layer may be of n-type doped GaAs material or p-type doped GaAs material. A first bonding metal film is formed on the buffer layer. A second bonding metal film is formed on the first surface. The first bonding metal film and the second bonding metal film may be formed by evaporation, sputtering, etc. A metal bonding process is performed on the conductive heat dissipation substrate 8 and the vertical-cavity surface-emitting laser chip so that the first bonding metal film and the second bonding metal film form a metal adhesion layer 7. The substrate 1 is thinned to 0-200 μm by grinding, etching, etc. When the base is thinned to 0 μm, the substrate 1 is removed.

Further, the light emitting layer comprises an active layer 4 and an oxide layer 3, one of the active layer 4 and the oxide layer 3 is connected to an n-type reflector layer 2 and the other is connected to a p-type reflector layer 5. An oxidation trench 9 is formed, extending at least from the first reflector layer to the second reflector layer. The oxidation trench 9 may be formed by an etching process. A wet oxidation process is performed in the oxidation trench 9 to form inwardly an oxidized region 3 from the oxidation trench, and the oxidized region 3 surrounds an unoxidized region 12. That is, when the wet oxidation process is adopted, an oxidized region 3 with a predetermined width is formed inwardly from the oxidation trench 9 (the left-right direction in the FIG. 5) by gradually diffusing in the oxide layer, while the remaining part is not oxidized. The unoxidized region 12 is used to define a light-emitting window from which the laser emitted from the light-emitting layer emits to the outside.

Further, the metal adhesion layer 7 is made of a material including at least one of the following metals: Ti, Sn, Ge, Ni, in, Zn, Pt, Cr, PD and Au; the metal bonding process may be performed at a temperature of 200° C.-900° C. and a pressure of 0.1 MPa-5 MPa.

The manufacturing method of the substrate-transferred vertical-cavity surface-emitting laser is described in the following by an example. The simple forming sequence and materials of each layer in the example are only used for illustration rather than limitation of the present invention, and the corresponding parts in the example may be replaced by the corresponding structures described in the above embodiments.

As shown in FIG. 2, a substrate 1 is provided, which may be of GaAs material.

A n-type reflector layer 2, an oxide layer 3, an active layer 4, a p-type reflector layer 5 and a buffer layer are sequentially formed on the substrate 1. The buffer layer may be made of one or laminated layers of the following materials: GaAs, AlGaAs, InGaAs and AlInGaAs. As one of the implementation modes, the buffer layer may be a p-type buffer layer 6 adopting p-type doped GaAs material.

A layer of metal film is evaporated on the p-type buffer layer 6, and the metal film is the first bonding metal film as stated above.

A metal conductive heat dissipation substrate 8 is provided, and a layer of metal film is evaporated on the conductive heat dissipation substrate 8, and the metal film is the second bonding metal film as stated above.

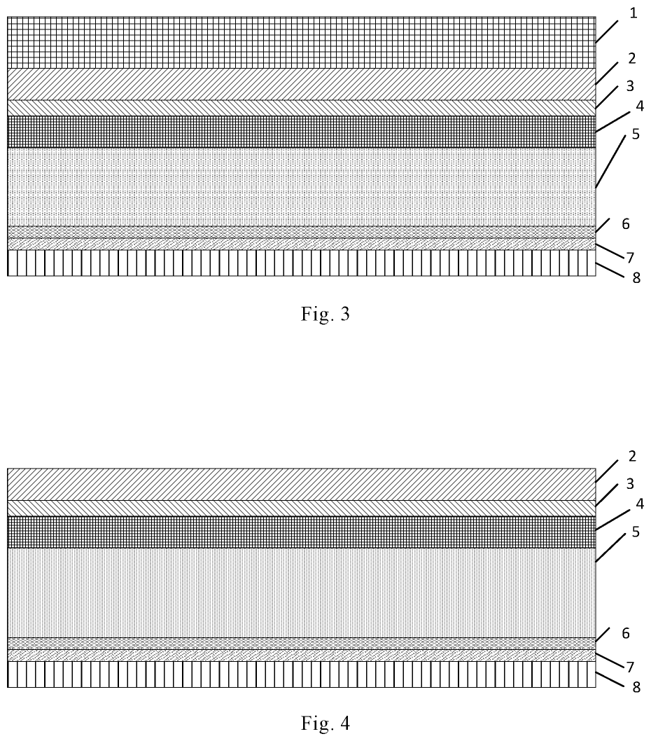

As shown in FIG. 3, the first bonding metal film and the second bonding metal film are adhered face-to-face, and the metal bonding process is performed in a metal bonding equipment so that the first bonding metal film and the second bonding metal film form a metal adhesion layer 7. The metal bonding process is performed at a temperature of 200° C.-900° C. A pressure of 0.1 MPa-5 MPa is applied between the substrate 1 and the conductive heat dissipation substrate 8.

As shown in FIG. 4, the substrate 1 is removed by grinding after the bonding is completed.

As shown in FIG. 5, a n-type electrode 10 is formed on the n-type reflector layer 2 after the substrate 1 has been removed. The n-type electrode 10 may be prepared by evaporation method. The n-type electrode 10 may be used as the reference point for photolithography calibration in the subsequent process so as to prepare a substrate-transferred vertical-cavity surface-emitting laser with high precision. The distance between the n-type electrode 10 and the oxidation trench 9 prepared subsequently is reduced so that a substrate-transferred vertical-cavity surface-emitting laser with strong current injection is provided. At the same time, the n-type electrode 10 can also be used as a metal contact pad of the subsequent metal connecting layer. The n-type electrode 10 may be made of a material including one of the following metals: Au, Ag, Pt, Ge, Ti and Ni or a combination thereof, and the material may be selected according to needs. Of course, the n-type electrode 10 can also be prepared after forming the oxidation trench 9.

In addition, an electrical isolation region 16 may be formed by proton or ion implantation from the second reflector layer to the first reflector layer. There is an uninsulated region in the electrical isolation region 16. The electrical isolation region 16 surrounds the light-emitting region of the vertical-cavity surface-emitting laser chip, that is, at least surrounds the unoxidized region, and the area of the electrical isolation region is generally larger than that of the unoxidized region 12. In this structure, the current is conducted via the uninsulated region and the unoxidized region 12 after the voltage is applied to the electrodes at both ends of the vertical-cavity surface-emitting laser chip.

A protective layer (not shown in the figure) covering the n-type electrode is formed on the n-type reflector layer 2. The protective layer may include a silicon oxide layer or a silicon nitride layer or a combination thereof.

As shown in FIG. 6, an oxidation trench 9 is formed by etching the protective layer. During the etching process, the protective layer protects the n-type electrode 10 and the n-type reflector layer 2.

A wet oxidation process is performed from the oxidation trench 9 so that an oxidized region 3 is formed inwardly from the oxidation trench 9, and the oxidized region 3 surrounds an unoxidized region 12.

A dielectric layer 13 is formed. The dielectric layer may include a silicon oxide layer or a silicon nitride layer or a combination thereof.

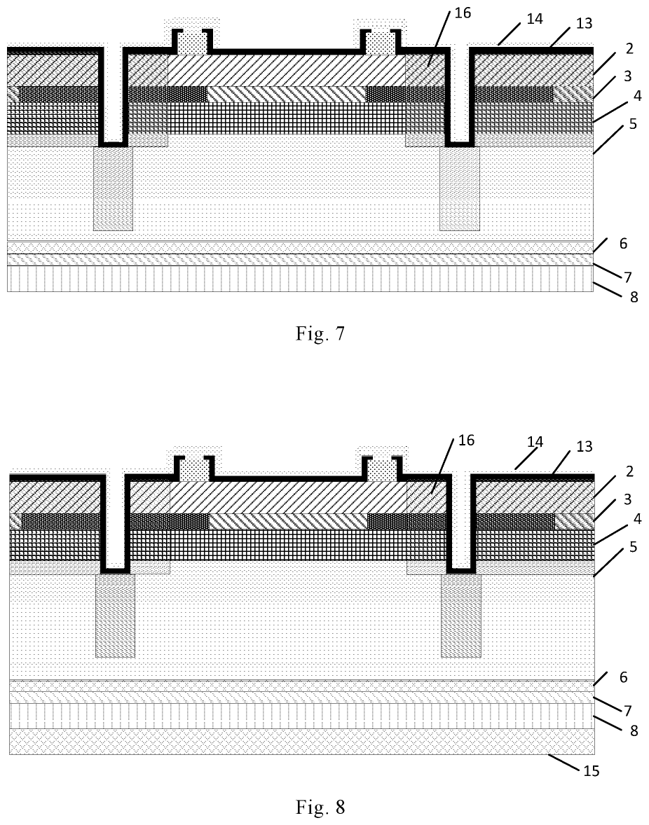

As shown in FIG. 7, the dielectric layer 13 above the n-type electrode 10 is removed, and a n-type electrode connecting layer 14 is formed by plating.

As shown in FIG. 8, a layer of p-type electrode 15 is plated on the conductive heat dissipation substrate 8.

It should be understood that orientation or positional relationship indicated by the terms “center”, “longitudinal”, “transverse”, “up”, “down”, “front”, “back”, “left”, “right”, “vertical”, “horizontal”, “top”, “bottom”, “inside”, “outside”, etc. are based on the orientation or position relationship shown in the attached drawings, which are merely for convenience of describing the present application and simplifying the description, rather than indicating or implying that the device or component referred to must have a specific orientation, or must be constructed and operated with a specific orientation, so they should not be construed as limiting the present application. Moreover, the terms “first” and “second” are used for descriptive purposes only and are not to be construed as indicating or implying relative importance or the number of technical features indicated. Thus a feature defined by “first” or “second” may explicitly or implicitly include one or more of the feature. In the description of the present application, unless otherwise specified, “multiple” or “a plurality of ” means two or more.

The above description is only the illustration of preferable embodiments of the present application and technical principles used therein. Those skilled in the art should understand that the scope of the present application is not limited to the technical solutions formed by the specific combination of the above technical features, but also cover other technical solutions formed by arbitrarily combining the above technical features or the equivalent features without departing from the inventive concept, for example, the technical solution formed by replacing the above features with the technical features with similar functions disclosed in the present application (but not limited to).

1. A substrate-transferred vertical-cavity surface-emitting laser, comprising:
a conductive heat dissipation substrate;
a metal adhesion layer; and
a vertical-cavity surface-emitting laser chip;
wherein a first surface of the conductive heat dissipation substrate is adhered to the vertical-cavity surface-emitting laser chip via the metal adhesion layer;
a second surface of the conductive heat dissipation substrate and the side of the vertical-cavity surface-emitting laser chip that is away from the conductive heat dissipation substrate contain contact electrodes, and
the first surface and the second surface are two opposite sides of the conductive heat dissipation substrate.

2. The substrate-transferred vertical-cavity surface-emitting laser according to claim 1, wherein the conductive heat dissipation substrate is a metal substrate made of a material including at least one of molybdenum, molybdenum copper alloy, tungsten, tungsten copper alloy, and chromium copper alloy; or
the conductive heat dissipation substrate is a silicon substrate.

3. The substrate-transferred vertical-cavity surface-emitting laser according to claim 1, wherein the vertical-cavity surface-emitting laser chip comprises a first reflector layer, a light emitting layer and a second reflector layer;
one of the first reflector layer and the second reflector layer is an n-type reflector layer, and the other is a p-type reflector layer.

4. The substrate-transferred vertical-cavity surface-emitting laser according to claim 3, wherein the first reflector layer and the second reflector layer are at least one of a Bragg reflector layer and a high-contrast grating layer.

5. The substrate-transferred vertical-cavity surface-emitting laser according to claim 3, wherein the light-emitting layer comprises an active layer and an oxide layer, and one of the active layer and the oxide layer is connected to the n-type reflector layer, and the other is connected to the p-type reflector layer;
the oxide layer includes an unoxidized region and an oxidized region arranged around the unoxidized region, and the unoxidized region is used to define a light-emitting window.

6. The substrate-transferred vertical-cavity surface-emitting laser according to claim 3, wherein the light emitting layer comprises an active layer and two oxide layers; the active layer is located between the two oxide layers; one of the oxide layers is connected to the n-type reflector layer, and the other oxide layer is connected to the p-type reflector layer;
each of the oxide layers includes an unoxidized region and an oxidized region arranged around the unoxidized region, and the unoxidized region is used to define a light-emitting window.

7. The substrate-transferred vertical-cavity surface-emitting laser according to claim 1, wherein the metal adhesion layer is made of a material including at least one of the following metals: Ti, Sn, Ge, Ni, In, Zn, Pt, Cr, Pd and Au.

8. The substrate-transferred vertical-cavity surface-emitting laser according to claim 5, wherein an electrical isolation region is formed by proton or ion implantation at least outside the light-emitting window, and the electrical isolation region covers at least a region of the oxide layer that is unoxidized.

9. The substrate-transferred vertical-cavity surface-emitting laser according to claim 8, wherein the electrical isolation region also covers at least a part of any one of the first reflector layer, the light-emitting layer, and the second reflector layer.

10. The substrate-transferred vertical-cavity surface-emitting laser according to claim 1, wherein the vertical-cavity surface-emitting laser film chip has a plurality of light-emitting regions arranged in a matrix or arranged randomly.

11. A manufacturing method of a substrate-transferred vertical-cavity surface-emitting laser, comprising the steps of:
providing a conductive heat dissipation substrate;
adhering a vertical-cavity surface-emitting laser chip to a first surface of the conductive heat dissipation substrate via a metal adhesion layer using a metal bonding process;
forming contact electrodes respectively on a second surface of the conductive heat dissipation substrate and the side of the vertical-cavity surface-emitting laser chip that is away from the conductive heat dissipation substrate, wherein the first surface and the second surface are two opposite sides of the conductive heat dissipation substrate.

12. The manufacturing method of a substrate-transferred vertical-cavity surface-emitting laser according to claim 11, wherein the vertical-cavity surface-emitting laser chip is formed by the following process:
providing a substrate;
forming a first reflector layer on the substrate;
forming a light-emitting layer on the first reflector layer; and
forming a second reflector layer on the light-emitting layer, wherein one of the first reflector layer and the second reflector layer is a n-type reflector layer, and the other is a p-type reflector layer.

13. The manufacturing method of a substrate-transferred vertical-cavity surface-emitting laser according to claim 12, wherein
a buffer layer is formed on the second reflector layer;
a first bonding metal film is formed on the buffer layer;
a second bonding metal film is formed on the first surface;
a metal bonding process is performed on the conductive heat dissipation substrate and the vertical-cavity surface-emitting laser chip so that the first bonding metal film and the second bonding metal film form the metal adhesion layer; and
the substrate is thinned to 0-200 μm.

14. The manufacturing method of a substrate-transferred vertical-cavity surface-emitting laser according to claim 13, wherein the light emitting layer comprises an active layer and an oxide layer, and one of the active layer and the oxide layer is connected to the n-type reflector layer, and the other is connected to the p-type reflector layer;
an oxidation trench is formed, which extends at least from the first reflector layer to the second reflector layer; and
a wet oxidation process is performed in the oxidation trench to form inwardly an oxidized region from the oxidation trench; the oxidized region surrounds an unoxidized region that is used to define a light-emitting window.

15. The manufacturing method of a substrate-transferred vertical-cavity surface-emitting laser according to claim 11, wherein the metal adhesion layer is made of a material including at least one of the following metals: Ti, Sn, Ge, Ni, In, Zn, Pt, Cr, Pd and Au; and
the metal bonding process is performed at a temperature of 200° C.-900° C. and a pressure of 0.1 MPa-5 MPa.
